(19) United States
(12) Patent Application Publication
(10) Pub. No.: US 2014/0063757 A1
(43) Pub. Date: Mar. 6, 2014

(54) JOINT STRUCTURE OF PACKAGE MEMBERS, METHOD FOR JOINING SAME, AND PACKAGE

(71) Applicant: KABUSHIKI KAISHA TOSHIBA, Tokyo (JP)

(72) Inventor: Kazutaka TAKAGI, Kanagawa-ken (JP)

(73) Assignee: Kabushiki Kaisha Toshiba, Tokyo (JP)

(21) Appl. No.: 13/871,149

(22) Filed: Apr. 26, 2013

(30) Foreign Application Priority Data
Sep. 3, 2012 (JP) 2012-193605

(51) Int. Cl. H05K 1/02; B23K 1/00

(52) U.S. Cl. CPC H05K 1/0271; B23K 1/0016
USPC 361/752; 228/101; 403/272; 361/748

(57) ABSTRACT

According to an embodiment, a joint structure of package members housing or holding an electronic component includes a first member, a second member joined to the first member, and a joint portion provided between the first member and the second member. The joint portion contains a metal element with a melting point of 400° C. or more and the metal element of 98 percent by weight or more.

### CROSS-REFERENCE TO RELATED APPLICATIONS

This application is based upon and claims the benefit of priority from Japanese Patent Application No. 2012-193605, filed on Sep. 3, 2012; the entire contents of which are incorporated herein by reference.

### FIELD

Embodiments are generally related to a joint structure of package members, a method for joining the same and a package.

### BACKGROUND

Electronic components such as semiconductor elements are bonded on a support substrate, which is mounted on a circuit board or the like. Most electronic components are hermetically sealed in a package with the support substrate in order to improve their reliability. Thus, the substrate and the package are required to be stable under the bonding temperature and the operating temperature of the electronic components. Hence, a plurality of members that constitute the substrate and the package are joined together using, for example, silver solder having a melting point higher than the bonding temperature and the operating temperature of the electronic components.

However, each of the substrate and the package is a composite body that includes circuit functions used for inputting and outputting signals and supplying electric power, heat dissipation functions for dissipating the heat of the electronic components to the outside, etc. When using silver solder, assembling the package members may be performed under high temperature. Thereby, concave or distortion of the package members may occur due to the difference between the linear expansion coefficients thereof, and may cause degradations in the characteristics and reliability of electronic components. Thus, a joint structure and a method for joining ₜhe package members are required, which may suppress the concave and distortion thereof and be stable under the bonding temperature and the operating temperature of electronic components.

### BRIEF DESCRIPTION OF THE DRAWINGS

FIGS. 1A and 1B are schematic views showing a package according to a first embodiment;

FIGS. 2A and 2B are schematic cross-sectional views showing a joining process of package members according to the first embodiment;

FIGS. 3A and 3B are schematic views showing another cross-section of the package according to the first embodiment;

FIGS. 4A to 4D are schematic views showing the manufacturing process of the package according to the first embodiment; and

FIGS. 5A and 5B are schematic views showing a semiconductor device according to a second embodiment.

### DETAILED DESCRIPTION

According to an embodiment, a joint structure of package members housing or holding an electronic component includes a first member, a second member joined to the first member, and a joint portion provided between the first member and the second member. The joint portion contains a metal element with a melting point of 400° C. or more and the metal element of 98 percent by weight or more.

Hereinbelow, embodiments are described with reference to the drawings. Identical components in the drawings are marked with the same reference numerals, and a detailed description thereof is omitted and different components are described as appropriate.

### First Embodiment

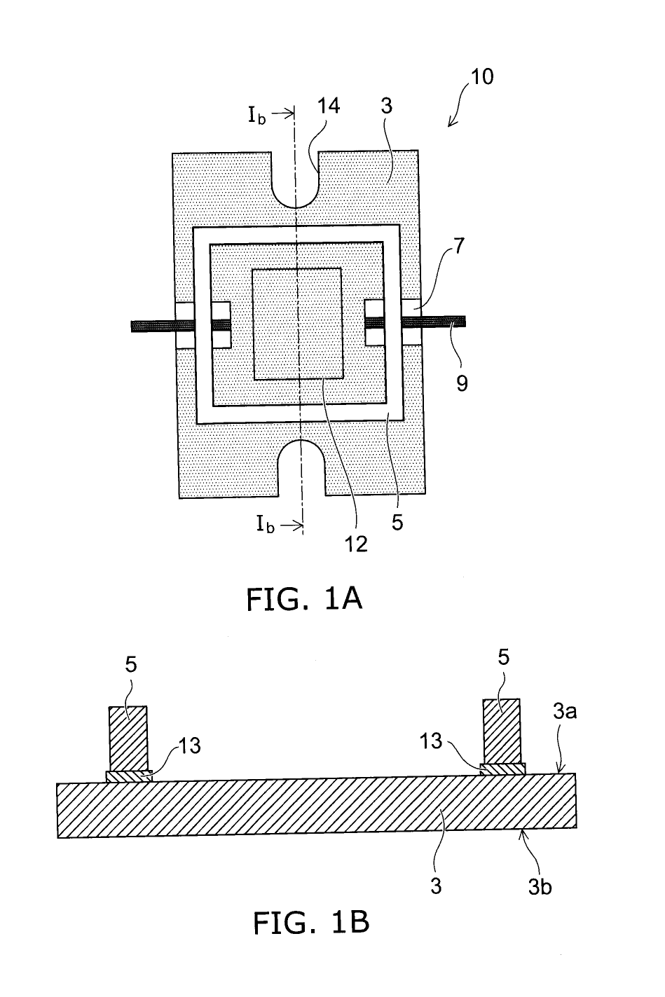

FIGS. 1A and 1B are schematic views showing a package 10 according to a first embodiment. FIG. 1A is a plan view of the package 10, and FIG. 1B is a cross-sectional view taken along line Ib-Ib in FIG. 1A. The package 10 is designed for housing an electronic component such as a semiconductor element, an optical semiconductor element, and a piezoelectric element in the interior thereof.

The package 10 shown in FIG. 1A includes a substrate 3, a frame 5, and a feed through terminal 7. The substrate 3 has a mounting portion 12, on which the electronic component and circuit element therearound are fixed, and a flange portion 14 for fixing the package to a circuit board using fixing screw. The frame 5 surrounds the mounting portion 12, and defines the boundary between the flange portion 14 and the mounting portion 12.

The feed through terminal 7 is provided between the substrate 3 and the frame 5, and is provided in order to electrically connect the electronic component hermetically sealed in the package to an external circuit. In the package 10, a pair of the feed through terminals 7 are provided, and a lead 9 connected to the external circuit is connected to each of the feed through terminals 7.

As shown in FIG. 1B, the substrate 3 and the frame 5 are connected together via a joint portion 13. For example, heat dissipation is important for a package that houses a power FET (field effect transistor) used for power amplification. Hence, a metal with high thermal conductivity, such as copper (Cu) and an alloy of copper and molybdenum (Mo), is used for the substrate 3. On the other hand, rigidity in bending is required for the frame 5, and for example Kovar material, which is an alloy combining iron (Fe), nickel (Ni), and cobalt (Co), is used for the frame 5.

The electronic component such as a semiconductor element is mounted on the upper face 3a (the mounting portion 12) of the substrate 3 using, for example, gold-tin (AuSn) alloy. During this process, the package 10 is heated to approximately 280 to 300° C. It is also possible to bond the semiconductor element using gold-germanium (AuGe) or gold-silicon (AuSi). When these alloys are used, the package 10 is heated to a temperature range of 350 to 370° C. Therefore, the remelting temperature of the joint portion 13 is preferably 400° C. or more. The larger the temperature difference between the bonding temperature and the remelting temperature (melting point) of the joint portion 13 makes the package 10 more stable.

For example, silver solder has a melting point of 780° C. or more, and is stable for bonding the electronic component. Thus, silver solder has been widely used for the joint portion 13. However, the melting point of silver solder may be too high, for suppressing concave or distortion, when joining the substrate 3 and the frame 5 together, since the difference in linear expansion coefficient between the substrate 3 made of copper alloy and the frame 5 made of Kovar is too large to avoid bending thereof during the cooling process.

Consequently, for example, when the package 10 housing a semiconductor element is fixed on a circuit board, a gap is formed between the lower face 3b of the substrate 3 and the circuit board, and reduces the heat dissipation. When a ceramic is used for one of the substrate 3 and the frame 5, a crack may occur in the ceramic portion.

In contrast, in the embodiment, the joint portion 13 contains one metal element with a melting point of 400° C. or more, and the metal element is contained in an amount of 98 percent by weight or more. The joint portion 13 contains, in a formation process thereof, fine particles, so called nanoparticles, made of a metal element having a melting point of 400° C. or more. The metal element is, for example, one of gold (Au), silver (Ag), copper (Cu), and nickel (Ni). The nanoparticle may have a protection layer containing a material other than these metal elements on its surface.

The nanoparticles can sinter or melt at a temperature lower than the melting point of the metal element, which is major constituent thereof, by several hundred degrees. Therefore, the substrate 3 and the frame 5 may be joined together at a temperature of 400 degrees or less, for example, by using the joint portion 13 containing nanoparticles. After joining the substrate 3 and the frame 5 together, the joint portion 13 includes a bulk metal containing the element of the nanoparticles. Since the bulk metal has the melting point of the metal element, the joint portion 13 is stable up to a temperature higher than the melting point of the nanoparticles by several hundred degrees. Thus, joining the substrate 3 and the frame 5 at a low temperature may provide a package which hardly has concave, distortion or residual stress, and which has the joint portion with higher melting point than the bonding temperature and the operating temperature of the electronic component.

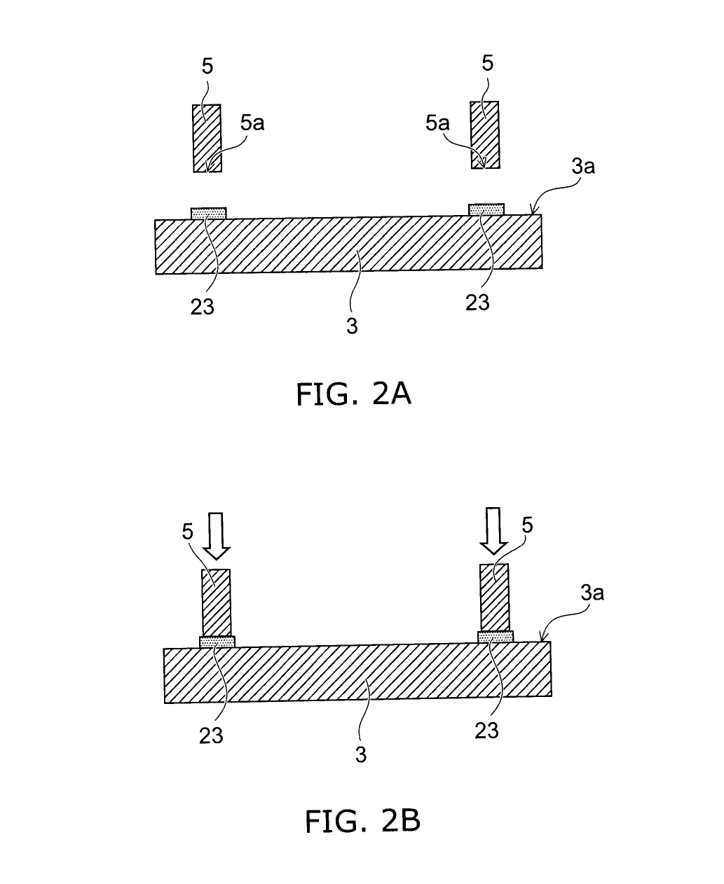

Next, the joining process of the substrate 3 and the frame 5 is described with reference to FIGS. 2A and 2B. FIG. 2A and FIG. 2B are schematic cross-sectional views showing the manufacturing process of the package 10.

The substrate 3 that is a first member and the frame 5 that is a second member are prepared in the manufacturing process of the package 10.

As shown in FIG. 2A, a joining material 23 including nanoparticles that contain, for example, silver (Ag) as a main ingredient is applied to the upper face 3a of the substrate 3. The joining material 23 is, for example, in a paste form in which Ag nanoparticles are scattered in an organic solvent. The particle size of the Ag nanoparticle is, for example, 10 to 100 nanometers (nm). The Ag nanoparticle may have a protection film on its surface. As the organic solvent, for example, a terpene alcohol is used. The joining material 23 may be applied using a dispenser or the printing method, for example.

Subsequently, as shown in FIG. 2B, the joining face 5a of the frame 5 is brought into contact with the joining face (the upper face 3a) of the substrate 3 via the joining material 23. Then, the substrate 3 and the frame 5 are heated in a temperature range of 300° C. to 400° C. while stacking them together, and applying a load thereto. Thereby, the organic solvent in the joining material 23 is vaporized away, leaving the Ag nanoparticles there between. Furthermore, the Ag nanoparticles are sintered; thus, the joint portion 13 containing bulk Ag is formed between the substrate 3 and the frame 5.

The melting point of bulk Ag is approximately 960° C. In contrast, the melting point of Ag nanoparticles with a particle size of several tens of nanometers is as low as 150° C. to 300° C. That is, the joint portion 13 containing bulk Ag can be formed, while keeping the joining material 23 containing Ag nanoparticles in a temperature range of 300° C. to 400° C. Thus, the package is formed at a low temperature of 300° C. to 400° C., avoiding concave and distortion of the substrate 3 and the frame 5, and the junction between the substrate 3 and the frame 5 is stable up to 900° C. or more, i.e. the melting point of the joint portion.

For example, the melting point of silver solder (Ague) with a copper (Cu) content of 28 percent by weight is 780° C. Therefore, by setting the concentration of Ag contained in the joint portion 13 to, for example, 90 percent by weight or more, the melting point thereof can be made higher than that of silver solder. That is, a package can be obtained that is more stable to the bonding temperature and operating temperature of the electronic component than a package in which the package members are joined together using silver solder.

When Au is selected as the metal element, the melting point of Au nanoparticles with a particle size of 10 to 100 nm is 50° C. to 500° C., whereas the melting point of bulk Au is 1064° C. It is also possible to use Au nanoparticles with a particle size of 50 nm to 500 nm. Au particles of this size can be sintered at a temperature of approximately 150° C. However, the melting point of an alloy in which another element is mixed into Au is much lower than the melting point of bulk Au. For example, the melting point of AuSi is 370° C., in which 6 percent by weight silicon is mixed. The melting point of AuGe is 356° C., in which 12 percent by weight germanium is mixed. Therefore, the joint portion 13 preferably has an Au content of, for example, 98 percent by weight or more in the case where Au nanoparticles are used.

When using Cu nanoparticles, the particle size thereof is preferably 10 to 100 nm, and the melting point of Cu nanoparticles of this size is 300 to 400° C. whereas the melting point of bulk Cu is 1080° C.

In the case of Ni nanoparticles, sintering temperature may be approximately 750° C., when the particle size is 100 nm, whereas the melting point of bulk Ni is 1450° C. Therefore, the sintering temperature may be significantly reduced by reducing the particle size. For example, the particle size of Ni nanoparticles may be set to approximately several tens of nanometers, preferably 10 nm or less; thereby, the sintering temperature may be further reduced.

The particle size in the specification refers to, for example, the average particle size measured by using a TEM (transmission electron microscope) image.

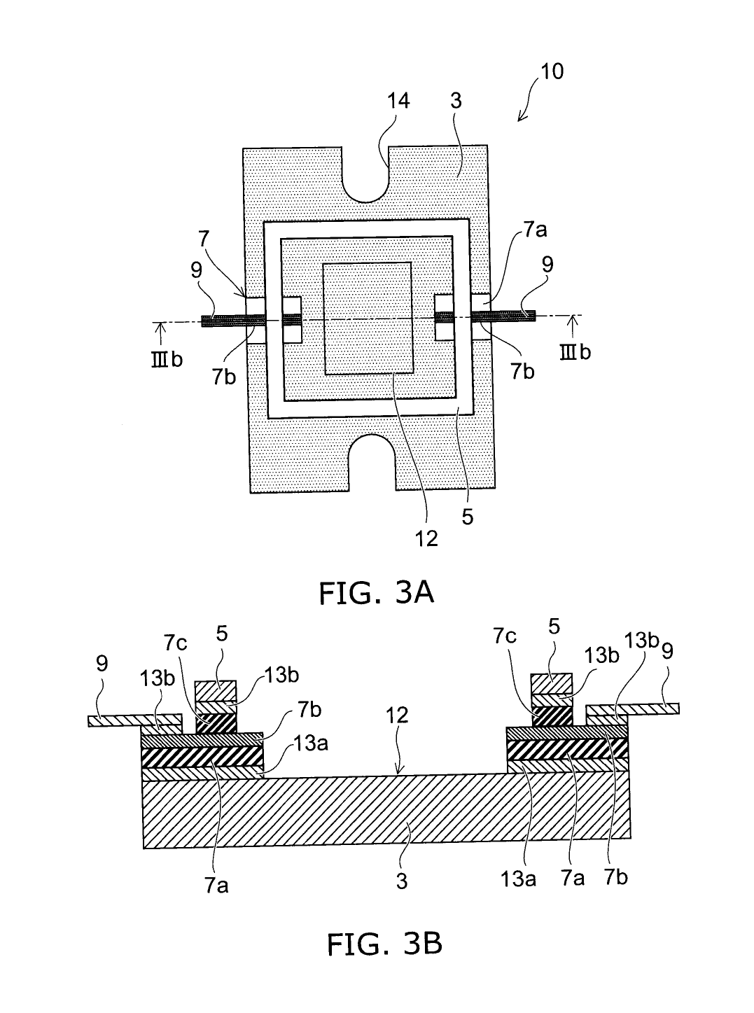

FIGS. 3A and 3B are schematic views showing another cross-section of the package 10 according to the first embodiment. FIG. 3A is a plan view of the package 10, and FIG. 3B is a cross-sectional view taken along line IIIb-IIIb in FIG. 3A. That is, FIG. 3B shows a cross section including the feed through terminal 7. The feed through terminal 7 inputs a signal into the electronic component fixed to the mounting portion 12, and outputs a signal from the electronic component.

As shown in FIG. 3B, in the feed through terminal 7, a strip line 7b is provided on a first insulating material 7a, and the lead 9 is connected to the strip line 7b. The first insulating material 7a includes, for example, a ceramic such as alumina (Al₂O₃). The characteristic impedance of the strip line 7b is set to 50Ω and is matched with the external circuit. Thereby, the transmission loss of high frequency signals may be reduced between the electronic component and the external circuit.

As shown in FIG. 3B, the feed through terminal 7 includes a second insulating material 7c provided on the first insulating material 7a via the strip line 7b. The second insulating material 7c electrically insulates the strip line 7b from the frame 5.

To fix the feed through terminal 7 between the substrate 3 and the frame 5, the substrate 3 and the feed through terminal 7 are connected together via a joint portion 13a, and the frame 5 and the feed through terminal 7 are joined together via a joint portion 13b. That is, as shown in FIG. 3B, the first insulating material 7a of the feed through terminal 7 and the substrate 3 are joined together via the joint portion 13a, and the second insulating material 7c and the frame 5 are joined together via the joint portion 13b.

The same joint structure may also be used for the connection between the strip line 7b in the feed through terminal 7 and the lead 9.

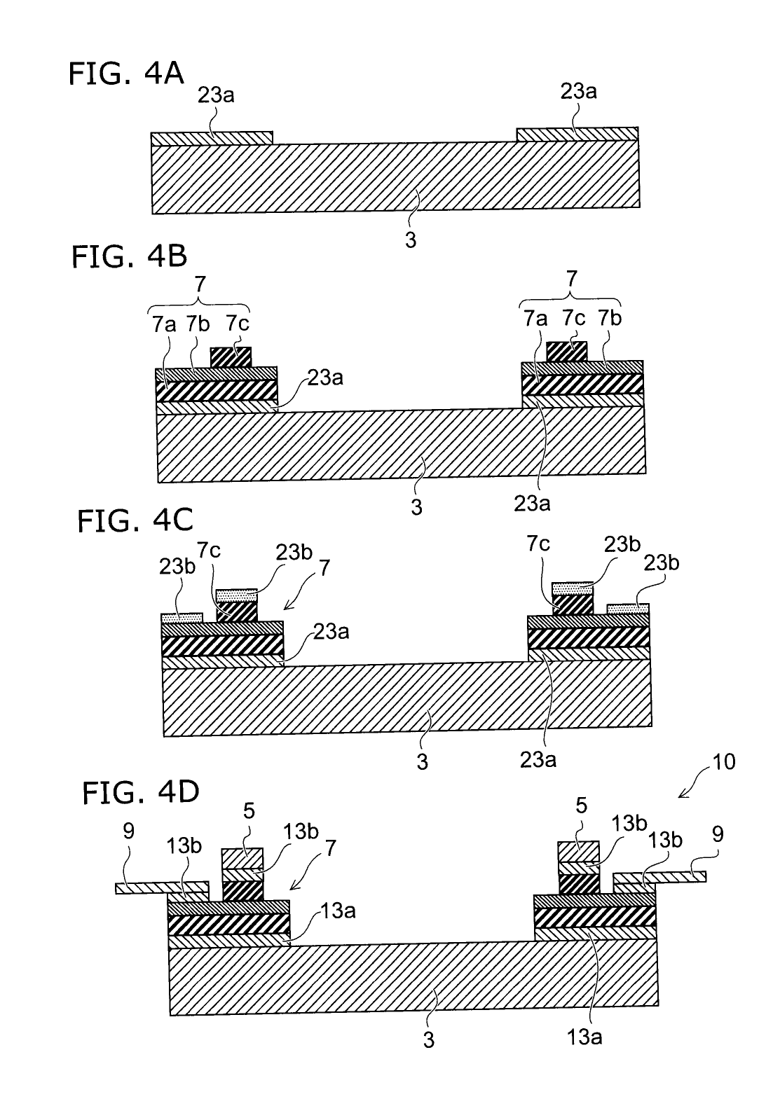

FIGS. 4A to 4D are schematic views showing the manufacturing process of the package 10 according to the first embodiment. FIG. 4A to FIG. 4D are schematic cross-sectional views showing the package in the respective processes.

As shown in FIG. 4A, a joining material 23a is applied to the upper face of the substrate 3. The joining material 23a contains, for example, Ag nanoparticles. The joining material 23a is applied using, for example, the printing method.

Next, as shown in FIG. 4B, the feed through terminal 7 is attached to the substrate 3 via the joining material 23a. That is, utilizing the viscosity of the joining material 23a, the feed through terminal 7 is tentatively fixed on the substrate 3. The feed through terminal 7 includes the first insulating material 7a, the strip line 7b, and the second insulating material 7c.

Next, as shown in FIG. 4C, a joining material 23b is applied to the end of the strip line 7b and the second insulating material 7c. The joining material 23b contains, for example, Ag nanoparticles, and is applied using a dispenser.

Next, as shown in FIG. 4D, the lead 9 is placed on the strip line 7b, and the frame 5 is placed on the second insulating material 7c. Subsequently, the substrate 3 and the feed through terminal 7 are heated in a temperature range of 300° C. to 400° C. while pressure is applied to the frame 5 and the lead 9. Thereby, the organic solvent is vaporized away from the joining materials 23a and 23b, and the Ag nanoparticles are sintered to form the joint portions 13a and 13b.

In the package 10 formed by the processes described above, the concave of the substrate 3, the distortion between the substrate 3 and the frame 5, the distortion between the feed through terminal 7 and the frame 5, and the distortion between the substrate 3 and the feed through terminal 7 may be suppressed. Furthermore, the joint portions 13a and 13b containing bulk Ag are stable up to temperatures of 900° C. or more, and the package may exhibit highly resistance to the environment of the bonding and operation of the electronic component.

Although the embodiment described above is explained as an example using a package that houses an electronic component, the embodiment is not limited thereto. For example, the embodiment can be applied also to a structure so called a carrier in which a member having a strip line may be joined to a substrate.

At least one of the first member and the second member may contain a ceramic material such as alumina (Al₂O₃) and aluminum nitride (AlN).

Although the manufacturing method described above explains an example in which the joining material 23 contains one kind of nanoparticle, the joining material 23 may contain two or more kinds of nanoparticle. In this case, elements and a compounding ratio may be selected so that the melting point of the bulk metal (alloy) included in the joint portion 13 becomes higher than a prescribed temperature after sintering or melting.

### Second Embodiment

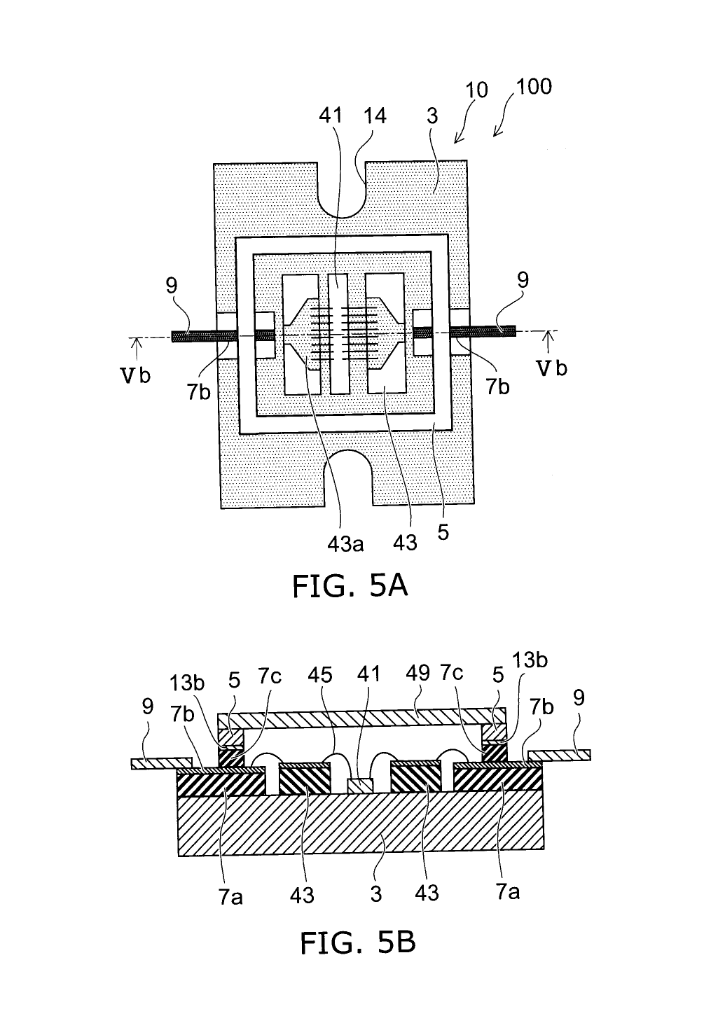

FIGS. 5A and 5B are schematic views showing a semiconductor device 100 according to a second embodiment. FIG. 5A is a plan view of the semiconductor device 100, and FIG. 5B is a cross-sectional view taken along line Vb-Vb shown in FIG. 5A.

The semiconductor device 100 is an example in which a power transistor 41 that amplifies a high frequency signal is hosed in the package 10 described in the first embodiment. The power transistor may be an HFET (hetero-junction field effect transistor) made of GaN, SiC, or the like, an LDMOSFET (lateral double-diffused MOS transistor) made of silicon, and the like. These are all power amplifying elements, and operate with large heat generation. Thus, a copper plate or copper alloy having effective heat dissipation is used for the substrate 3 in the package 10.

As shown in FIG. 5A, the transistor 41 and two circuit substrates 43 are mounted on the mounting portion 12 of the package 10. A conductive pattern 43a is provided on the surface of the circuit substrate 43, and both conductive patterns 43a electrically connect a plurality of gate electrodes and a plurality of drain electrodes (or source electrodes) of the transistor 41 to the strip lines 7b. Alumina (Al₂O₃), for example, is used for the circuit substrate 43.

As shown in FIG. 5B, the transistor 41 and the circuit substrate 43 are bonded on the substrate 3. AuSn solder, for example, is used for bonding. Thereby, the transistor 41 is electrically connected to the substrate 3, improving the heat dissipation characteristic. The transistor 41 may be grounded via the substrate 3, for example.

A lid 49 is fixed on the frame 5 in order to hermetically seal the transistor 41. Nitrogen gas, for example, is enclosed in the package 10 to stabilize the operation of the transistor 41, and to improve reliability thereof. The lid 49 may be soldered to the frame 5 using, for example, AuSn.

As described above, in the package 10, the substrate 3 and the frame 5 are joined together and the feed through terminal 7, the substrate 3, and the frame 5 are joined together via the joint portions 13a and 13b. Since the joint portions 13a and 13b are provided at a temperature lower than the temperature of silver soldering, for example, the concave or distortion may be suppressed in the substrate 3, the feed through terminal 7, and the frame 5. The joint portions 13a and 13b join the package members stably up to temperatures of 900° C. or more. Thereby, the lower face of the substrate 3 can be attached to a circuit board or a heat sink without the gap, improving the heat dissipation from the transistor 41. Furthermore, the transistor 41 may operate with stable characteristics, and may have improved reliability.

In a transistor made of a wide gap semiconductor such as GaN and SiC, the available operating temperature thereof reaches 600° C. Also in such a case, the joint portions 13a and 13b may be provided with higher melting point than the operating temperature, and the semiconductor device may operate stably.

The package 10 according to the embodiment may house or hold also an optical semiconductor element such as an LED and a laser and a piezoelectric element such as a SAW filter, not limited to the transistor mentioned above.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A joint structure of package members housing or holding an electronic component, the joint structure comprising:
a first member;
a second member joined to the first member; and
a joint portion provided between the first member and the second member and containing a metal element with a melting point of 400° C. or more, the joint portion containing the metal element of 98 percent by weight or more.

2. The joint structure according to claim 1, wherein the metal element is one of gold (Au), silver (Ag), copper (Cu), and nickel (Ni).

3. The joint structure according to claim 1, wherein the first member is made of copper or copper alloy; and the second member is made of an alloy containing iron (Fe).

4. The joint structure according to claim 1, wherein at least one of the first member and the second member contains an insulating material.

5. The joint structure according to claim 1, wherein at least one of the first member and the second member contains a ceramic material.

6. The joint structure according to claim 1, wherein a remelting temperature of the joint portion is 400° C. or more.

7. A method for joining package members housing or holding an electronic component, the method comprising:
placing a first member and a second member into contact with each other via a joining material containing a fine particle, the fine particle containing a metal element with a melting point of 400° C. or more and having a particle size of 500 nm or less; and
heating the first member and the second member contacting with each other via the joining material.

8. The method according to claim 7, wherein the joining material is provided on the first member.

9. The method according to claim 7, wherein a temperature of the heating is 400° C. or less.

10. The method according to claim 7, wherein the joining material includes a fine particle containing at least one of gold (Au), silver (Ag), copper (Cu), and nickel (Ni).

11. The method according to claim 7, wherein the joining material contains silver of 90 percent by weight or more.

12. The method according to claim 7, wherein the joining material contains gold of 98 percent by weight or more.

13. The method according to claim 7, wherein the fine particle is a gold particle with a particle size of 50 nm to 500 nm.

14. The method according to claim 7, wherein the fine particle is a copper particle with a particle size of 10 nm to 100 nm.

15. The method according to claim 7, wherein the fine particle is a nickel particle with a particle size of 10 nm or less.

16. The method according to claim 7, wherein the joining material contains two or more kinds of fine particle.

17. A package comprising:
a substrate for fixing an electronic component thereto; and
a frame surrounding a portion for fixing the electronic component, the frame being joined to the substrate via a joint portion containing one metal element with a melting point of 400° C. or more, the joint portion containing the metal element of 98 percent or more.

18. The package according to claim 17, further comprising a feed through terminal for inputting a signal to the electronic component, or outputting a signal from the electronic component,
wherein the substrate and the feed through terminal are joined together via a joint portion, and the frame and the feed through terminal are joined together via a joint portion, each of the joint portions containing one metal element with a melting point of 400° C. or more, and the metal element of 98 percent or more.

19. The package according to claim 17, wherein the substrate includes a copper plate or copper alloy.

20. The package according to claim 17, further comprising a lid fixed to the frame,
wherein the electronic component is hermetically sealed therein.
